(19) United States
(12) Patent Application Publication
(10) Pub. No.: US 2016/0181517 A1
(43) Pub. Date: Jun. 23, 2016

(54) Geometrically Enhanced Resistive Random Access Memory (RRAM) Cell And Method Of Forming Same

(71) Applicant: Silicon Storage Technology, Inc., San Jose, CA (US)

(72) Inventors: Feng Zhou, Fremont, CA (US); Xian Liu, Sunnyvale, CA (US); Nhan Do, Saratoga, CA (US); Hieu Van Tran, San Jose, CA (US); Hung Quoc Nguyen, Fremont, CA (US)

(21) Appl. No.: 14/582,089

(22) Filed: Dec. 23, 2014

(51) Int. Cl. H01L 45/00; H01L 27/24; G11C 13/00

(52) U.S. Cl. CPC H01L 45/085; G11C 13/0011; G11C 13/0069; G11C 13/0097; H01L 45/1233; H01L 45/1253; H01L 45/146; H01L 45/16; H01L 27/2463

(57) ABSTRACT

A memory device (and method of making and using the memory device) includes a first electrode of conductive material, a second electrode of conductive material, and a layer transition metal oxide material that includes first and second elongated portions meeting each other at a sharp corner. Each of the first and second elongated portions is disposed between and in electrical contact with the first and second electrodes.

### FIELD OF THE INVENTION

The present invention relates to non-volatile memory, and more specifically to resistive random access memory.

### BACKGROUND OF THE INVENTION

Resistive random access memory (RRAM) is a type of nonvolatile memory. Generally, RRAM memory cells each include a resistive dielectric material layer sandwiched between two conductive electrodes. The dielectric material is normally insulating. However, by applying the proper voltage across the dielectric layer, a conduction path (typically referred to as a filament) can be formed through the dielectric material layer. Once the filament is formed, it can be “reset” (i.e., broken or ruptured, resulting in a high resistance state across the RRAM cell) and set (i.e., re-formed, resulting in a lower resistance state across the RRAM cell), by applying the appropriate voltages across the dielectric layer. The low and high resistance states can be utilized to indicate a digital signal of “1” or “0” depending upon the resistance state, and thereby provide a reprogrammable non-volatile memory cell that can store a bit of information.

FIG. 1 shows a conventional configuration of an RRAM memory cell 1. The memory cell 1 includes a resistive dielectric material layer 2 sandwiched between two conductive material layers that form top and bottom electrodes 3 and 4, respectively.

FIGS. 2A-2D show the switching mechanism of the dielectric material layer 2. Specifically, FIG. 2A shows the resistive dielectric material layer 2 in its initial state after fabrication, where the layer 2 exhibits a relatively high resistance. FIG. 2B shows the formation of a conductive filament 7 through the layer 2 by applying the appropriate voltage across the layer 2. The filament 7 is a conductive path through the layer 2, such that the layer exhibits a relatively low resistance across it (because of the relatively high conductivity of the filament 7). FIG. 2C shows the formation of a rupture 8 in filament 7 caused by the application of a “reset” voltage across the layer 2. The area of the rupture 8 has a relatively high resistance, so that layer 2 exhibits a relatively high resistance across it. FIG. 2D shows the restoration of the filament 7 in the area of the rupture 8 caused by the application of a “set” voltage across layer 2. The restored filament 7 means the layer 2 exhibits a relatively low resistance across it. The relatively low resistance of layer 2 in the “formation” or “set” states of FIGS. 2B and 2D respectively can represent a digital signal state (e.g. a “1”), and the relatively high resistance of layer 2 in the “reset” state of FIG. 2C can represent a different digital signal state (e.g. a “0”). The RRAM cell 1 can repeatedly be “reset” and “set,” so it forms an ideal reprogrammable nonvolatile memory cell.

One of the drawbacks of RRAM memory cells is that the voltage and current needed to form the filament are relatively high (and could be significantly higher than the voltages needed to set and reset the memory cell). There is a need for an RRAM memory cell that requires a lower voltage and current for forming the cell's filament.

### BRIEF SUMMARY OF THE INVENTION

The aforementioned problems and needs are addressed by a memory device that includes a first electrode of conductive material, a second electrode of conductive material, and a layer transition metal oxide material that includes first and second elongated portions meeting each other at a sharp corner, wherein each of the first and second elongated portions is disposed between and in electrical contact with the first and second electrodes.

A method of making a memory device includes forming a first electrode of conductive material, forming a second electrode of conductive material, and forming a layer of transition metal oxide material that includes first and second elongated portions meeting each other at a sharp corner, wherein each of the first and second elongated portions is disposed between and in electrical contact with the first and second electrodes.

A method of programming and erasing a memory device having a first electrode of conductive material, a second electrode of conductive material, and a layer of transition metal oxide material that includes first and second elongated portions meeting each other at a sharp corner, wherein each of the first and second elongated portions is disposed between and in electrical contact with the first and second electrodes, and a conductive filament extending through the layer of transition metal oxide material. The method includes rupturing the filament by applying a first voltage across the first and second electrodes such that the layer of transition metal oxide material provide a first electrical resistance between the first and second electrodes, and restoring the ruptured filament by applying a second voltage across the first and second electrodes such that the layer of transition metal oxide material provide a second electrical resistance between the first and second electrodes that is lower than the first electrical resistance.

Other objects and features of the present invention will become apparent by a review of the specification, claims and appended figures.

### BRIEF DESCRIPTION OF THE DRAWINGS

FIG. 1 is a side cross sectional view of a conventional Resistive Random Access Memory (RRAM) cell.

FIG. 2A is a side cross sectional view of the resistive dielectric layer of the conventional RRAM cell in its initial state after fabrication.

FIG. 2B is a side cross sectional view of the resistive dielectric layer of the conventional RRAM cell in its formed state.

FIG. 2C is a side cross sectional view of the resistive dielectric layer of the conventional RRAM cell in its reset state.

FIG. 2D is a side cross sectional view of the resistive dielectric layer of the conventional RRAM cell in its set state.

FIG. 3 is a side cross sectional view of the Resistive Random Access Memory (RRAM) cell of the present invention.

FIGS. 4A-4C are side cross sectional views showing the steps in forming the RRAM cell.

FIGS. 5A-5C are side cross sectional views showing the steps in forming an alternate embodiment of the RRAM cell.

FIG. 6A is a side cross sectional view of the inventive RRAM cell in its initial state.

FIG. 6B is a side cross sectional view of the inventive RRAM cell in its formed state.

FIG. 6C is a side cross sectional view of the inventive RRAM cell in its reset state.

FIG. 6D is a side cross sectional view of the inventive RRAM cell in its set state.

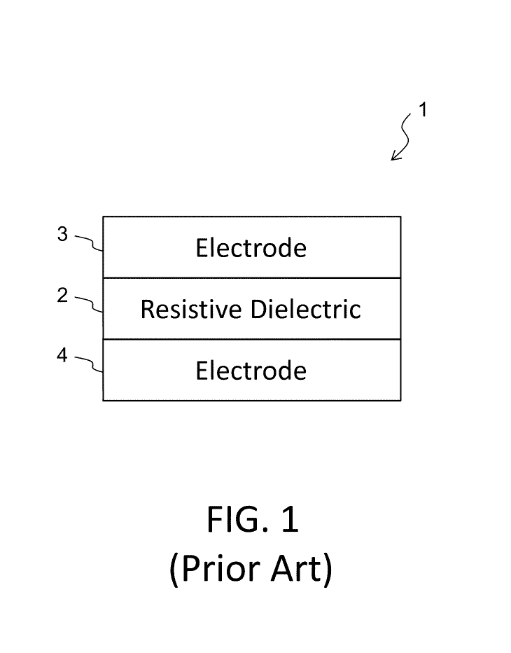

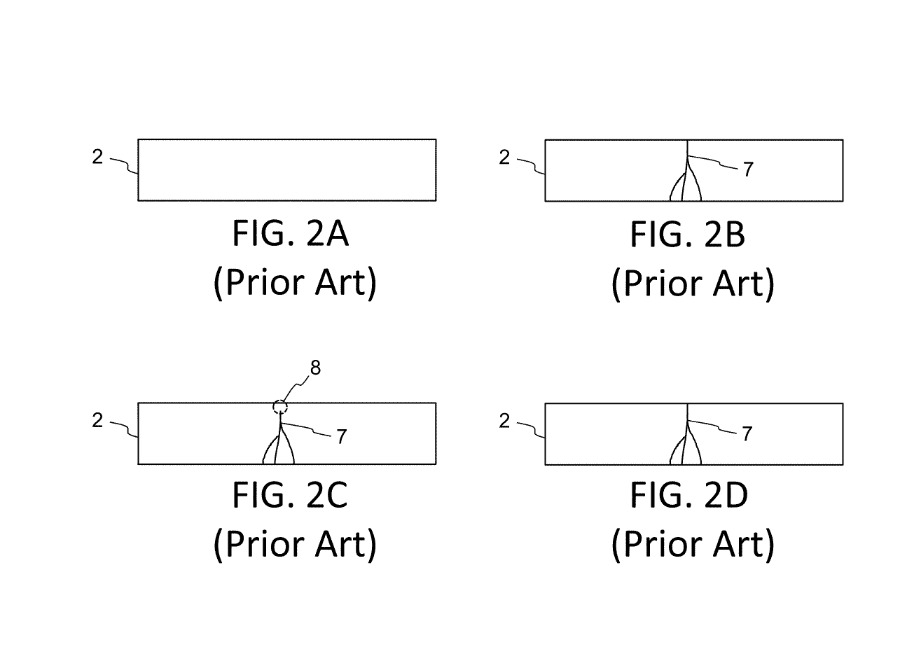

### DETAILED DESCRIPTION OF THE INVENTION

The present invention is a geometrically enhanced RRAM cell with electrodes and resistive dielectric layer configured in a manner that reduces the voltage necessary for forming the cell's conductive filament. It has been discovered that by providing a sharp corner in the resistive dielectric layer at a point between the two electrodes significantly reduces the voltage and current necessary to effectively form the filament.

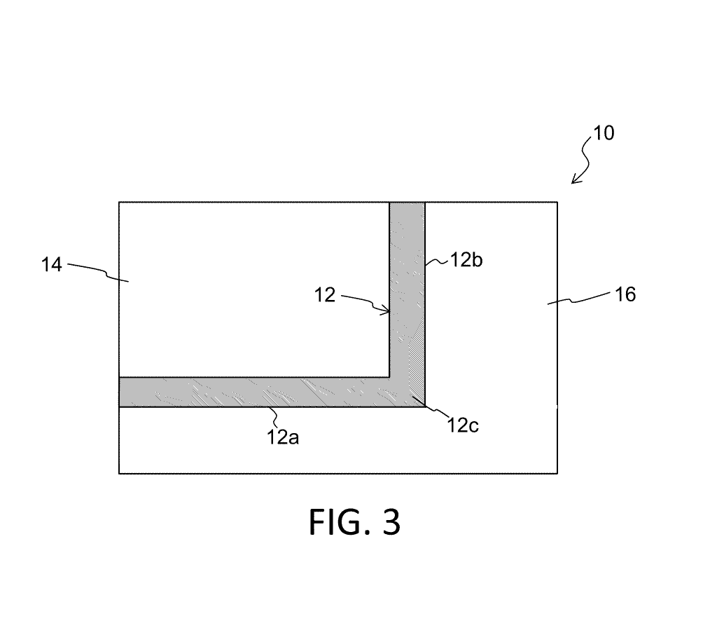

FIG. 3 illustrates the general structure of the inventive RRAM memory cell 10, which includes a resistive dielectric layer 12 having elongated first and second portions 12a and 12b respectively that meet at a right angle. Specifically, first portion 12a is elongated and extends horizontally, and second portion 12b is elongated and extends vertically, such that the two portions 12a and 12b meet at a sharp corner 12c (i.e. resistive dielectric layer 12 has an “L” shape). The first electrode 14 is disposed above horizontal layer portion 12a and to the left of vertical layer portion 12b. The second electrode 16 is disposed below horizontal layer portion 12a and to the right of vertical layer portion 12b. Therefore, each of the first and second layer portions 12a and 12b are disposed between and in electrical contact with the electrodes 14 and 16. Electrodes 14 and 16 can be formed of appropriately conductive material such as W, Al, Cu, Ti, Pt, TaN, TiN, etc., and resistive dielectric layer 12 is made of a transition metal oxide, such as HfOx, TaOx, TiOx, WOx, VOx, CuOx, or multiple layers of such materials, etc.). Alternatively, resistive dielectric layer 12 can be a composite of discrete sub-layers with one or more sub-layers of transition metal oxides (e.g. layer 12 could be multiple layers: a Hf layer disposed between a TaOx layer and a HfOx layer). It has been discovered that filament formation through layer 12 at the sharp corner 12c can occur at lower voltages than if the dielectric layer 12 were planar due to the enhanced electric field at the sharp corner 12c.

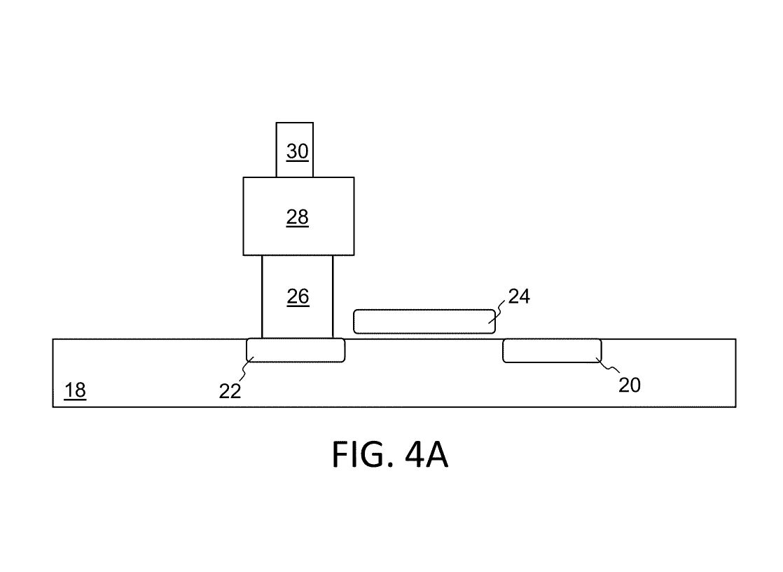

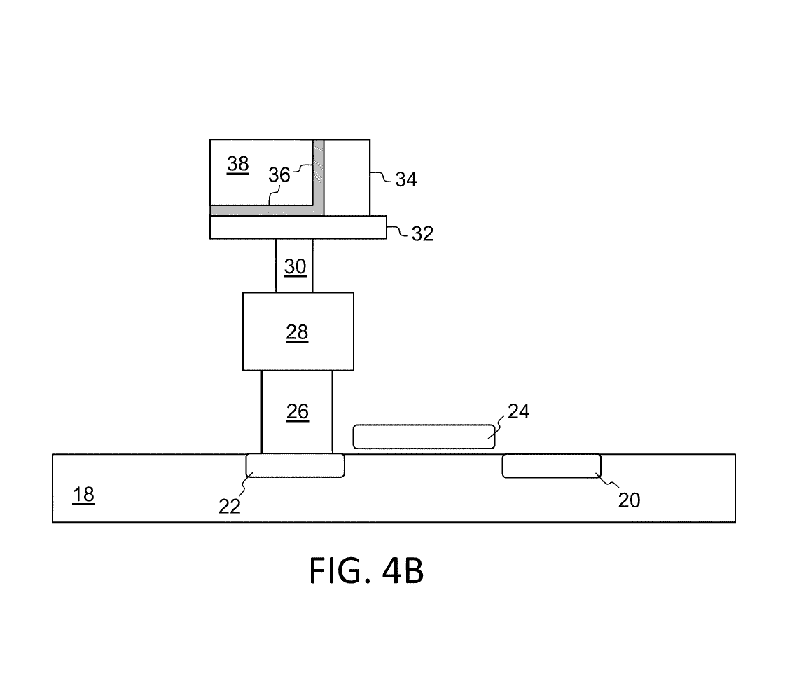

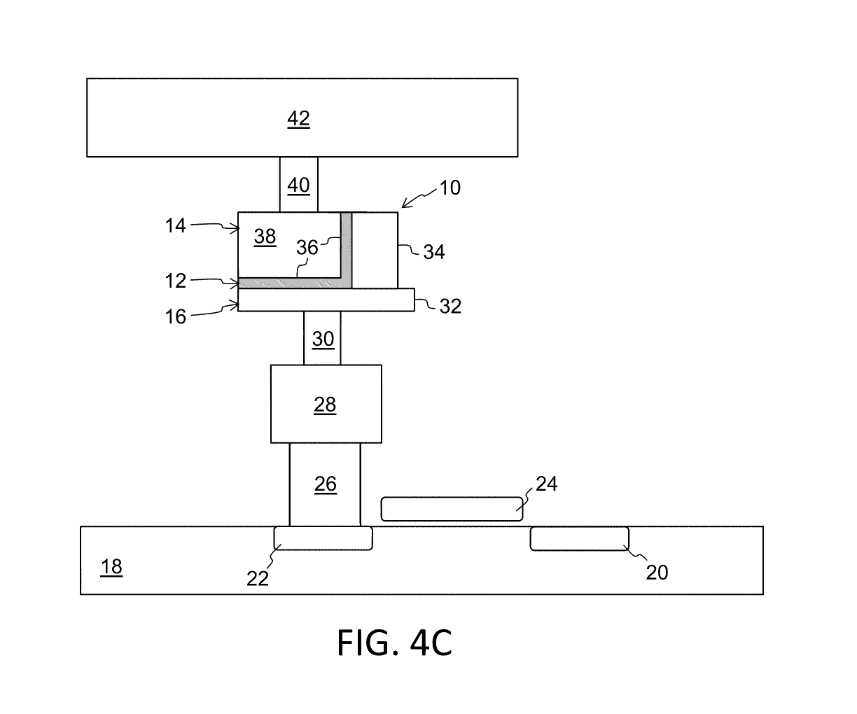

FIGS. 4A-4C show the steps in forming the inventive RRAM memory cell 10 and related circuitry. The process begins by forming a select transistor on a substrate 18. The transistor includes source/drain regions 20/22 formed in the substrate 18 and a gate 24 disposed over and insulated from the channel region there between. On the drain 22 is formed conductive blocks 26 and 28, and conductive plug 30, as illustrated in FIG. 4A.

A layer of conductive material 32 is formed over plug 30 (e.g. using photolithography techniques well known in the art). A block of conductive material 34 is then formed over just a portion of the layer of conductive material 32. The corner where layer 32 and block 34 meet can be sharpened by plasma treatment. Then, transition metal oxide layer 36 is deposited on layer 32 and on the vertical portion of block 34. This is followed by a conductive material deposition and CMP etch back to form a block of conductive material 38 on layer 36. The resulting structure is shown in FIG. 4B.

A conductive plug 40 is formed on conductive block 38. A conductive line (e.g. bit line) 42 is formed over and connected to plug 40. The resulting structure is shown in FIG. 4C. Layer 32 and block 34 form the lower electrode 16, layer 36 forms the resistive dielectric layer 12, and block 38 forms the upper electrode 14, of RRAM cell 10.

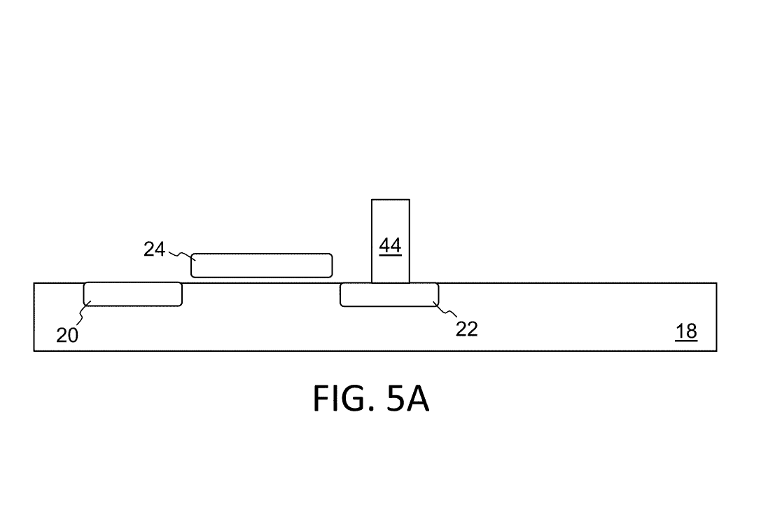

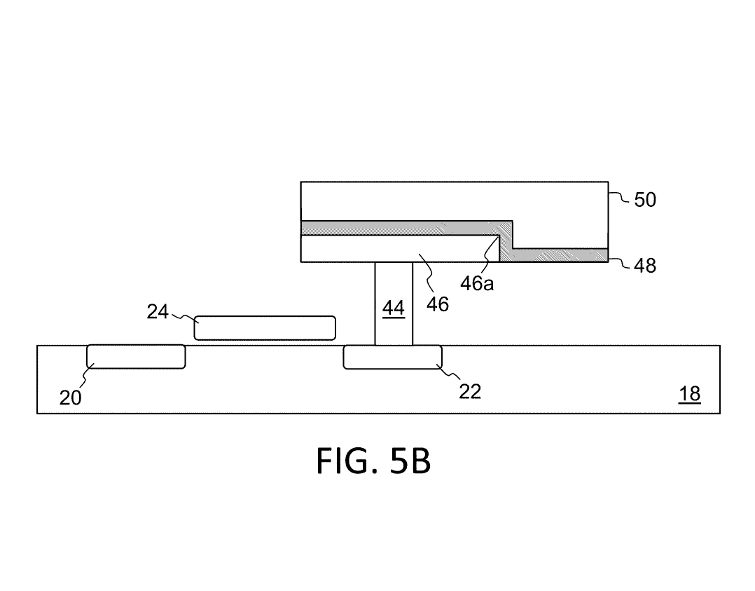

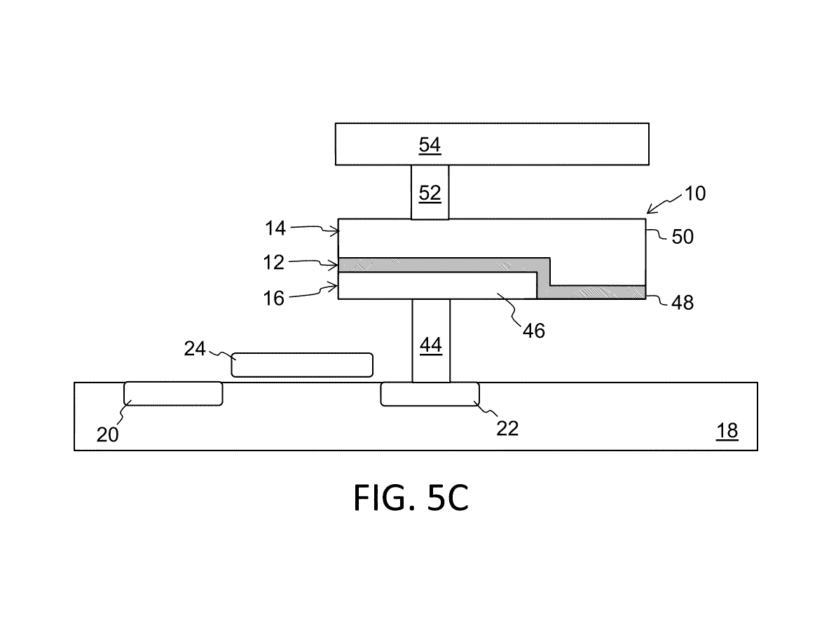

FIGS. 5A-5C show the steps in forming an alternate embodiment of the inventive RRAM memory cell 10 and related circuitry. The process begins by forming the select transistor on a substrate 18 as described above (source/drain regions 20/22 formed in the substrate 18, and gate 24 disposed over and insulated from the channel region there between). On the drain 22 is formed a conductive block 44, as illustrated in FIG. 5A.

A layer of conductive material 46 is formed over block 44. A transition metal oxide layer 48 is deposited on block 46, along one of the vertical side surfaces of block 46, and away from block 46. This is followed by forming a layer of conductive material 50 by deposition and CMP etch back. The resulting structure is shown in FIG. 5B. Hence, there exists a sharp tip corner 46a of material 46 that is pointing to another sharp tip corner intersection of layers 48/50. This enhances the localized field at top corner 46a which reduces the necessary forming voltage.

A conductive plug 52 is formed on conductive layer 50. A conductive line (e.g. bit line) 54 is formed over and connected to plug 52. The resulting structure is shown in FIG. 5C. Layer 46 forms the lower electrode 16, layer 48 forms the resistive dielectric layer 12, and layer 50 forms the upper electrode 14, of RRAM cell 10.

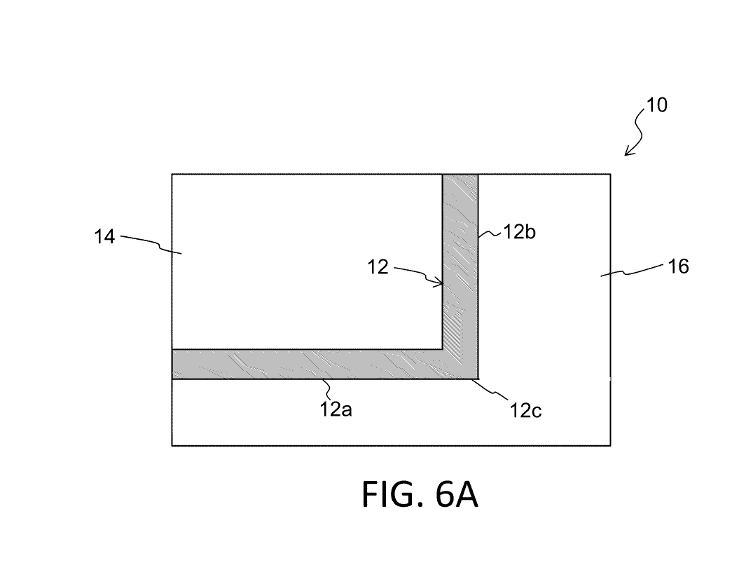

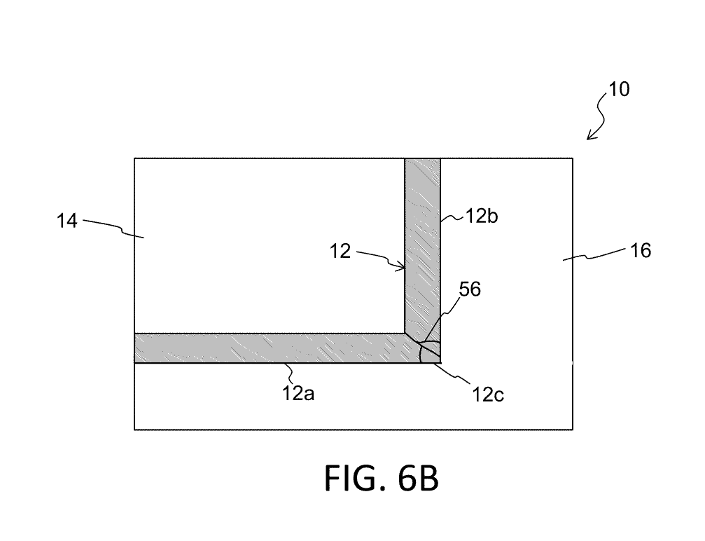

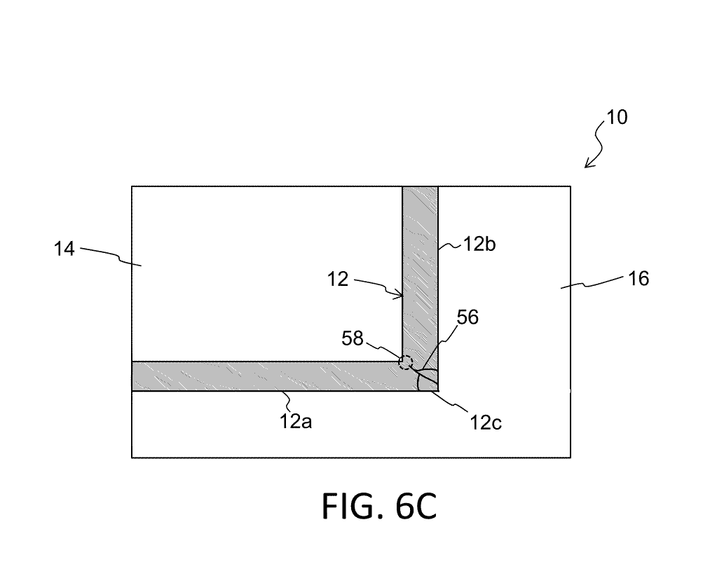

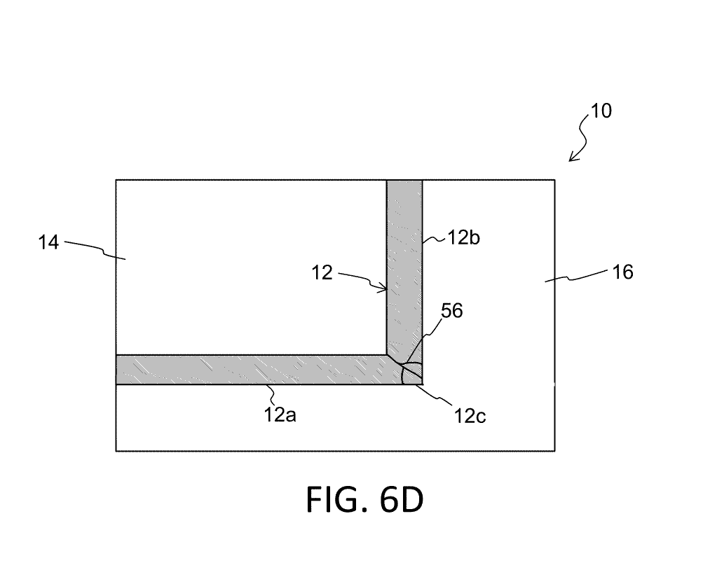

As a non-limiting example, RRAM cell 10 in its original state is shown in FIG. 6A. Electrodes 14 and 16 are formed of CU and resistive dielectric layer 12 is formed of HfOx. In order to form a conductive filament 56 through the sharp corner 12c as shown in FIG. 6B, a voltage difference of about 3-6V is applied across electrodes 14 and 16. In order to reset the RRAM cell 10 by forming a rupture 58 in filament 56 as shown in FIG. 6C, a voltage difference of about 1-4 V is applied across electrodes 14 and 16. In order to set the RRAM cell 10 by removing rupture 58 in filament 56 as shown in FIG. 6D, a voltage difference of about 1-4 V is applied across electrodes 16 and 14 (i.e. reverse polarity relative to forming and reset voltages).

It is to be understood that the present invention is not limited to the embodiment(s) described above and illustrated herein, but encompasses any and all variations falling within the scope of the appended claims. For example, references to the present invention herein are not intended to limit the scope of any claim or claim term, but instead merely make reference to one or more features that may be covered by one or more of the claims. Materials, processes and numerical examples described above are exemplary only, and should not be deemed to limit the claims. Further, as is apparent from the claims and specification, not all method steps need be performed in the exact order illustrated or claimed, but rather in any order that allows the proper formation of the RRAM memory cell of the present invention. Lastly, single layers of material could be formed as multiple layers of such or similar materials, and vice versa.

It should be noted that, as used herein, the terms “over” and “on” both inclusively include “directly on” (no intermediate materials, elements or space disposed there between) and “indirectly on” (intermediate materials, elements or space disposed there between). Likewise, the term “adjacent” includes “directly adjacent” (no intermediate materials, elements or space disposed there between) and “indirectly adjacent” (intermediate materials, elements or space disposed there between), “mounted to” includes “directly mounted to” (no intermediate materials, elements or space disposed there between) and “indirectly mounted to” (intermediate materials, elements or spaced disposed there between), and “electrically coupled” includes “directly electrically coupled to” (no intermediate materials or elements there between that electrically connect the elements together) and “indirectly electrically coupled to” (intermediate materials or elements there between that electrically connect the elements together). For example, forming an element “over a substrate” can include forming the element directly on the substrate with no intermediate materials/elements there between, as well as forming the element indirectly on the substrate with one or more intermediate materials/elements there between.

1. A memory device, comprising:
a first electrode of conductive material;
a second electrode of conductive material;
a layer of transition metal oxide material that includes first and second elongated portions meeting each other at a sharp corner, wherein each of the first and second elongated portions includes elongated opposing first and second surfaces and is disposed between and in electrical contact with the first and second electrodes such that:
a portion of the first surface of the first elongated portion adjacent the sharp corner is in electrical contact with the first electrode and a portion of the second surface of the first elongated portion adjacent the sharp corner is in electrical contact with the second electrode, and
a portion of the first surface of the second elongated portion adjacent the sharp corner is in electrical contact with the first electrode and a portion of the second surface of the second elongated portion adjacent the sharp corner is in electrical contact with the second electrode.

2. The memory device of claim 1, wherein the first elongated portion extends in a first direction, the second elongated portion extends in a second direction, and the first and second directions are orthogonal to each other.

3. The memory device of claim 1, wherein the layer of transition metal oxide material is L-shaped.

4. The memory device of claim 1, wherein the transition metal oxide material includes at least one of HfOx, TaOx, TiOx, WOx, Vox, and CuOx.

5. The memory device of claim 1, wherein the layer of transition metal oxide material includes a first sublayer of Hf disposed between a second sublayer of TaOx and a third sublayer of HfOx layer.

6. The memory device of claim 1, further comprising:
a substrate of a first conductivity type;
first and second regions of a second conductivity type different than the first conductivity type formed in a surface of the substrate;
a conductive gate disposed over and insulated from the substrate, and between the first and second regions;
wherein the second electrode is electrically coupled to the second region.

7. A method of making a memory device, comprising:
forming a first electrode of conductive material;
forming a second electrode of conductive material; and
forming a layer of transition metal oxide material that includes first and second elongated portions meeting each other at a sharp corner, wherein each of the first and second elongated portions includes elongated opposing first and second surfaces and is disposed between and in electrical contact with the first and second electrodes such that:
a portion of the first surface of the first elongated portion adjacent the sharp corner is in electrical contact with the first electrode and a portion of the second surface of the first elongated portion adjacent the sharp corner is in electrical contact with the second electrode, and
a portion of the first surface of the second elongated portion adjacent the sharp corner is in electrical contact with the first electrode and a portion of the second surface of the second elongated portion adjacent the sharp corner is in electrical contact with the second electrode.

8. The method of claim 7, further comprising:
forming a conductive filament across the layer of transition metal oxide material by applying a first voltage across the first and second electrodes.

9. The method of claim 7, wherein the first elongated portion extends in a first direction, the second elongated portion extends in a second direction, and the first and second directions are orthogonal to each other.

10. The method of claim 7, wherein the layer of transition metal oxide material is L-shaped.

11. The method of claim 7, wherein the transition metal oxide material includes at least one of HfOx, TaOx, TiOx, WOx, Vox, and CuOx.

12. The method of claim 7, wherein the forming of the layer of transition metal oxide material comprises:
forming a first sublayer of Hf;
forming a second sublayer of TaOx; and
forming a third sublayer of HfOx layer,
wherein the first sublayer is disposed between the second and third sublayers.

13. The method of claim 7, further comprising:
forming first and second regions of a first conductivity type in a surface of a substrate of a second conductivity type different than the first conductivity type;
forming a conductive gate disposed over and insulated from the substrate, and between the first and second regions;
electrically coupling the second electrode to the second region.

14. A method of programming and erasing a memory device having a first electrode of conductive material, a second electrode of conductive material, and a layer of transition metal oxide material that includes first and second elongated portions meeting each other at a sharp corner, wherein each of the first and second elongated portions includes elongated opposing first and second surfaces and is disposed between and in electrical contact with the first and second electrodes, and a conductive filament extending through the layer of transition metal oxide material, such that:
a portion of the first surface of the first elongated portion adjacent the sharp corner is in electrical contact with the first electrode and a portion of the second surface of the first elongated portion adjacent the sharp corner is in electrical contact with the second electrode, and
a portion of the first surface of the second elongated portion adjacent the sharp corner is in electrical contact with the first electrode and a portion of the second surface of the second elongated portion adjacent the sharp corner is in electrical contact with the second electrode;
the method comprising:
rupturing the filament by applying a first voltage across the first and second electrodes such that the layer of transition metal oxide material provide a first electrical resistance between the first and second electrodes; and
restoring the ruptured filament by applying a second voltage across the first and second electrodes such that the layer of transition metal oxide material provide a second electrical resistance between the first and second electrodes that is lower than the first electrical resistance.

15. The method of claim 14, wherein the first elongated portion extends in a first direction, the second elongated portion extends in a second direction, and the first and second directions are orthogonal to each other.

16. The method of claim 14, wherein the layer of transition metal oxide material is L-shaped.

17. The method of claim 14, wherein the transition metal oxide material includes at least one of HfOx, TaOx, TiOx, WOx, Vox, and CuOx.

18. The method of claim 14, wherein the layer of transition metal oxide material includes a first sublayer of Hf disposed between a second sublayer of TaOx and a third sublayer of HfOx layer.
